(19) United States
(12) Patent Application Publication
(10) Pub. No.: US 2013/0236632 A1
(43) Pub. Date: Sep. 12, 2013

(54) Graphene Combinatorial Processing

(71) Applicants: Sandip Niyogi, San Jose, CA (US); Sean Barstow, San Jose, CA (US); Dipankar Pramanik, Saratoga, CA (US)

(72) Inventors: Sandip Niyogi, San Jose, CA (US); Sean Barstow, San Jose, CA (US); Dipankar Pramanik, Saratoga, CA (US)

(73) Assignee: Intermolecular, Inc., San Jose, CA (US)

(21) Appl. No.: 13/622,549

(22) Filed: Sep. 19, 2012

Related U.S. Application Data
(60) Provisional application No. 61/609,228, filed on Mar. 9, 2012.

(51) Int. Cl. C23C 16/26

(52) U.S. Cl. 427/8; 977/891

(57) ABSTRACT

A method for optimizing graphene synthesis is provided. The method includes providing a substrate having a plurality of site isolated regions defined thereon and depositing a metal layer within each region of the plurality of site isolated regions. The metal layer is combinatorially deposited among the plurality of site isolated regions. The method includes synthesizing a graphene layer over each metal layer within each region of the plurality of site isolated regions and evaluating grain boundary profiles in the synthesized graphene layer over each metal layer within each region of the plurality of site isolated regions.

### CROSS-REFERENCE TO RELATED APPLICATION

This application claims priority to U.S. Provisional Patent Application Ser. No. 61/609,228 filed on Mar. 9, 2012, which is herein incorporated by reference for all purposes.

### BACKGROUND

Combinatorial processing enables rapid evaluation of semiconductor processes. The systems supporting the combinatorial processing are flexible to accommodate the demands for running the different processes either in parallel, serial or some combination of the two.

Graphene is a possible electronic material replacement due to its high carrier mobility and saturation velocity as the search for faster and smaller transistors continues. However, the manufacturing of graphene is not conducive to conventional semiconductor manufacturing techniques as the graphene is typically deposited on a metal substrate and then transferred to a dielectric surface. A continuing effort to adapt the manufacturing of graphene in order to viably commercially produce devices utilizing graphene is ongoing.

It is within these contexts that the embodiments arise.

### SUMMARY

In some embodiments, a method for optimizing graphene synthesis is provided. The method includes providing a substrate having a plurality of site isolated regions defined thereon and depositing a metal layer within each region of the plurality of site isolated regions. The metal layer is combinatorially deposited among the plurality of site isolated regions. The method includes synthesizing a graphene layer over each metal layer within each region of the plurality of site isolated regions. The method includes evaluating grain boundary profiles in the synthesized graphene layer over each metal layer within each region of the plurality of site isolated regions.

These and further aspects are described more fully below.

### BRIEF DESCRIPTION OF THE DRAWINGS

FIG. 1 illustrates a simplified schematic diagram providing an overview of the High-Productivity Combinatorial (HPC) screening process for use in evaluating materials, unit processes, and process sequences for the manufacturing of semiconductor devices in accordance with some embodiments.

FIG. 2 illustrates a flowchart of a general methodology for combinatorial process sequence integration that includes site-isolated processing and/or conventional processing in accordance with some embodiments.

FIG. 3 is a simplified schematic diagram illustrating the combinatorial process workflow and the different parameters that can be combinatorially varied for graphene processing in accordance with some embodiments.

FIG. 4 is a simplified schematic diagram illustrating an alternative representation from FIG. 3 for the properties that may be varied to evaluate a graphene process in accordance with some embodiments.

FIG. 5 is a simplified schematic diagram illustrating the process flow for the graphitization of an amorphous carbon layer disposed over any suitable substrate in accordance with some embodiments of the invention.

### DETAILED DESCRIPTION

Those skilled in the relevant art will recognize that many changes can be made to the embodiments described, while still obtaining the beneficial results. It will also be apparent that some of the desired benefits of the embodiments described can be obtained by selecting some of the features of the embodiments without utilizing other features. Accordingly, those who work in the art will recognize that many modifications and adaptations to the embodiments described are possible and may even be desirable in certain circumstances, and are a part of the invention. Thus, the following description is provided as illustrative of the principles of the embodiments of the invention and not in limitation thereof, since the scope of the invention is defined by the claims. It will be obvious, however, to one skilled in the art, that the embodiments described may be practiced without some or all of these specific details. In other instances, well known process operations have not been described in detail in order not to unnecessarily obscure the present invention.

The embodiments describe methods and apparatuses for combinatorial optimization of graphene synthesis. The high productivity combinatorial (HPC) system is utilized to optimize graphene synthesis on a substrate surface through a deposition technique. Graphene synthesis through a vapor deposition processes may include the use of a transition metal as a catalyst. The crystal structure of the transition metal and its grain size impact quality of the graphene film deposited thereon. The process of optimizing the properties of the catalyst for graphene synthesis may be evaluated through the HPC system in order to understand how certain underlayers affect the surface morphology and crystal structure of the thin films of graphene deposited thereover. Through site isolated combinatorial physical vapor deposition (PVD), the substrate preparation and interface preparation may be evaluated under differing conditions. The substrate preparation may utilize different catalytic materials, e.g., Aluminum or Nickel, among others, as well as different morphologies for these materials and differing deposition processing conditions. The interface preparation includes modification of the environment and process conditions of the interface of the substrate surface onto which the graphene was to be deposited. Processing variables for the graphene deposition and post processing conditions may also be varied within the HPC system to optimize the graphene synthesis. Thus, with the numerous parameters to vary, the HPC system and the primary, secondary and tertiary testing, is ideally suited to evaluate the matrix of variables in order to optimize the graphene synthesis to identify a suitable process for full wafer processing.

Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to (i) test different materials, (ii) test different processing conditions within each unit process module, (iii) test different sequencing and integration of processing modules within an integrated processing tool, (iv) test different sequencing of processing tools in executing different process sequence integration flows, and combinations thereof in the manufacture of devices such as integrated circuits. In particular, there is a need to be able to test (i) more than one material, (ii) more than one processing condition, (iii) more than one sequence of processing conditions, (iv) more than one process sequence integration flow, and combinations thereof, collectively known as “combinatorial process sequence integration,” on a single monolithic substrate without the need for consuming the equivalent number of monolithic substrates per materials, processing conditions, sequences of processing conditions, sequences of processes, and combinations thereof. This can greatly improve both the speed and reduce the costs associated with the discovery, implementation, optimization, and qualification of materials, processes, and process integration sequences required for manufacturing.

High Productivity Combinatorial (HPC) processing techniques have been successfully adapted to wet chemical processing such as etching and cleaning HPC processing techniques have also been successfully adapted to deposition processes such as physical vapor deposition (PVD), atomic layer deposition (ALD), and chemical vapor deposition (CVD).

Systems and methods for HPC processing are described in U.S. Pat. No. 7,544,574, filed on Feb. 10, 2006; U.S. Pat. No. 7,824,935, filed on Jul. 2, 2008; U.S. Pat. No. 7,871,928, filed on May 4, 2009; U.S. Pat. No. 7,902,063, filed on Feb. 10, 2006; and U.S. Pat. No. 7,947,531, filed on Aug. 28, 2009 each of which is incorporated by reference herein. Systems and methods for HPC processing are further described in U.S. patent application Ser. No. 11/352,077, filed on Feb. 10, 2006; U.S. patent application Ser. No. 11/419,174, filed on May 18, 2006; U.S. patent application Ser. No. 11/674,132, filed on Feb. 12, 2007; and U.S. patent application Ser. No. 11/674,137, filed on Feb. 12, 2007. The aforementioned patent applications claim priority from provisional patent application 60/725,186 filed Oct. 11, 2005. Each of the aforementioned patent applications and the provisional patent application are incorporated by reference herein.

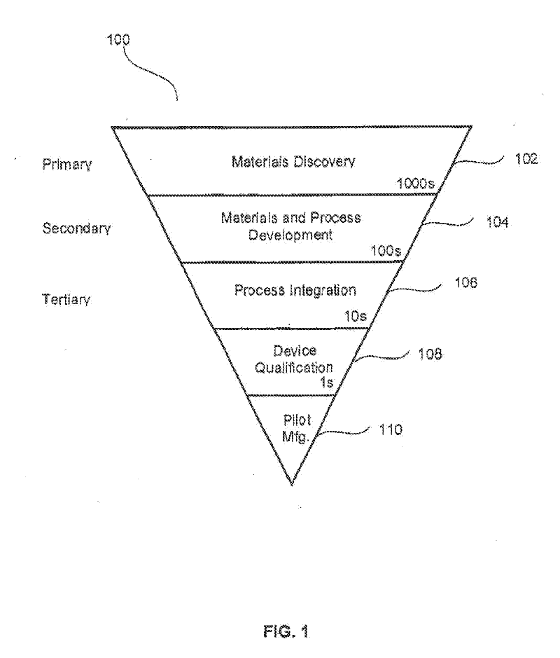

FIG. 1 illustrates a schematic diagram 100 for implementing combinatorial processing and evaluation using primary, secondary, and tertiary screening. The schematic diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as electronic testers and imaging tools (e.g., microscopes).

The materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106 where tens of materials and/or processes and combinations are evaluated. The tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing 110.

The schematic diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways.

This application benefits from High Productivity Combinatorial (HPC) techniques described in U.S. patent application Ser. No. 11/674,137, filed on Feb. 12, 2007, which is hereby incorporated by reference in its entirety. Portions of the '137 application have been reproduced below to enhance the understanding of the embodiments disclosed herein. The embodiments disclosed enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as material characteristics of components utilized within the unit manufacturing operations. Rather than only considering a series of local optimums, i.e., where the best conditions and materials for each manufacturing unit operation is considered in isolation, the embodiments described below consider effects of interactions introduced due to the multitude of processing operations that are performed and the order in which such multitude of processing operations are performed when fabricating a device. A global optimum sequence order is therefore derived, and as part of this derivation, the unit processes, unit process parameters, and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform throughout each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameters (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

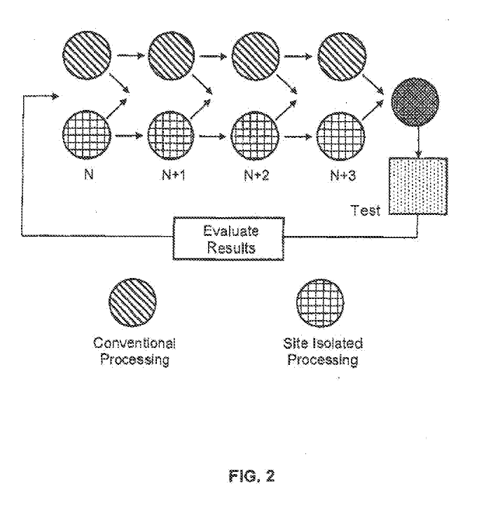

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g., from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments described herein perform the processing locally in a conventional manner, i.e., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

As stated above, under combinatorial processing operations the processing conditions at different regions can be controlled independently. According to some embodiments of the present invention, individual apparatuses for controlled deposition onto different regions of a substrate for optimization of interlayer parameters are provided.

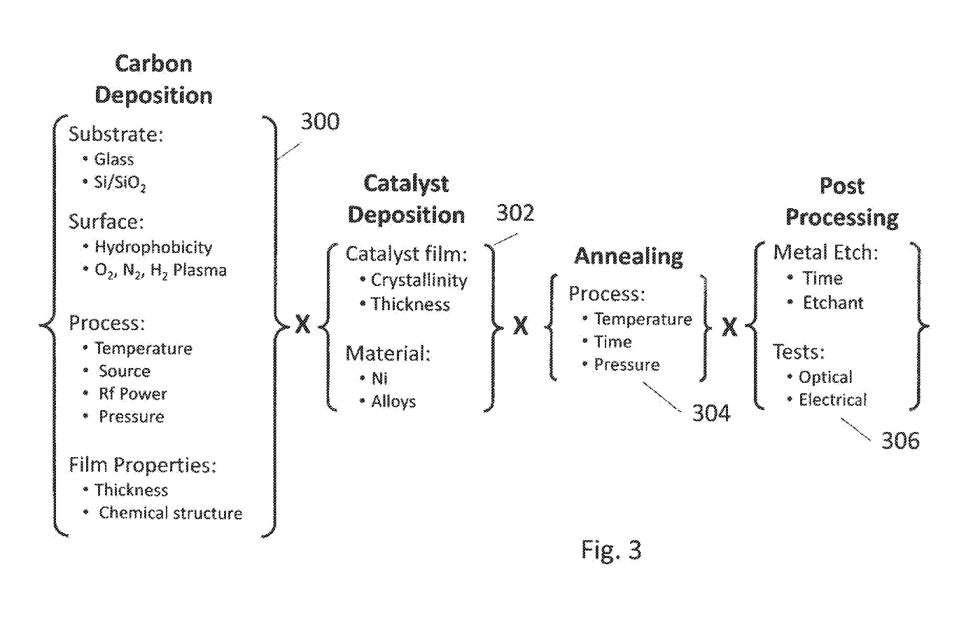

FIG. 3 is a simplified schematic diagram illustrating the combinatorial process workflow and the different parameters that can be combinatorially varied for graphene processing in accordance with some embodiments. Matrix 300 includes carbon deposition variables related to the substrate, substrate surface, process, and film properties that may be varied in order to evaluate the graphene processing. As illustrated, the substrate may be a glass substrate or a silicon-based substrate. The surface parameters capable of being evaluated through combinatorial processing include hydrophobicity and a type of plasma utilized in the carbon deposition process. Process parameters include temperature, fluid source composition for the deposition, radio frequency power, pressure in the deposition chamber, etc. The film properties for the graphene layer may be evaluated in terms of thickness and chemical structure. With regard to matrix 302 catalyst deposition variables may be evaluated during the combinatorial process. The catalyst deposition properties include the crystallinity in thickness of the catalyst film, which is a metal film such as aluminum, nickel, or alloys of the two in some embodiments. The catalyst may be an underlayer over which the carbon is deposited in some embodiments. In other embodiments, the catalyst may be deposited over a carbon film. Matrix 304 includes process properties that may be varied for the annealing process in accordance with some embodiments. The process properties for the annealing process include temperature, time and pressure. Matrix 306 includes post processing properties and tests. Metal etch properties of Matrix 306 include time and the composition of the etchant. Tests performed on the processed graphene material include optical tests and electrical tests.

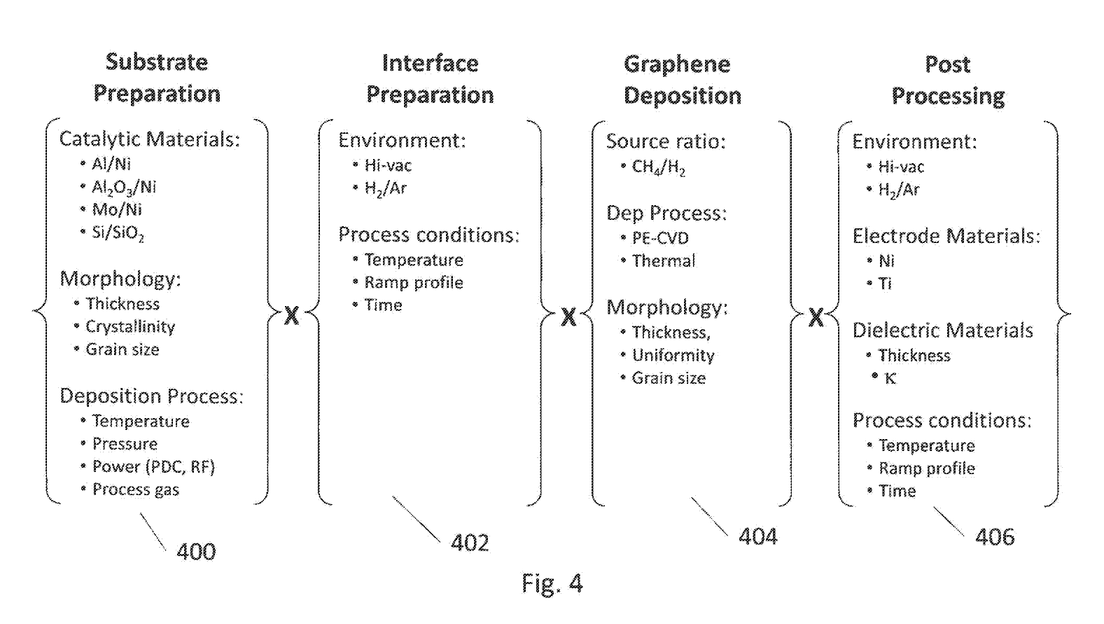

FIG. 4 is a simplified schematic diagram illustrating an alternative representation from FIG. 3 for the properties that may be varied to evaluate a graphene process in accordance with some embodiments. FIG. 4 includes substrate preparation matrix 400, interface preparation matrix 402, graphene deposition matrix 404, and post processing matrix 406. Each of the matrices 400 through 406 represents material, parameters, etc., that may be varied in order to identify an optimal graphene processing technique. Substrate preparation matrix 400 includes a list of different catalytic materials provided as an underlayer on top of which the graphene is deposited in some embodiments. The various catalytic materials include aluminum, nickel, molybdenum, and silicon. Different alloys of these catalytic materials may also be included. It should be appreciated that the list of catalytic materials is provided for illustrative purposes only and not meant to be limiting. Morphological properties, such as thickness, crystallinity, and grain size of the underlayer in some embodiments may also be combinatorially evaluated. The deposition process for the underlayer may have varied processing parameters such as temperature, pressure, power, and process gas composition. Interface preparation matrix 402 includes environmental and process conditions that may be varied during the combinatorial processing. The environmental conditions include vacuum and the atmosphere in the chamber for the processes, such as argon and/or hydrogen. The process conditions include temperature, ramp profile of the temperature, and time in some embodiments. Graphene deposition matrix 404 includes process variables related to the source for the deposition, the deposition process variables, and morphological properties. The ratio of the fluid source providing the carbon layer may vary the ratio of methane and hydrogen in some embodiments. The deposition process may be a plasma enhanced chemical vapor deposition or some form of thermal processing. Morphological properties for the graphene deposition include thickness, uniformity, and grain size of the graphene layer in accordance with some embodiments. Post processing matrix 406 provides example environmental, electrode material, dielectric material, and process condition parameters that may be varied during the combinatorial processing in order to optimize the graphene technique. The environmental parameters include vacuum level, and the fluid atmosphere for the post processing environment, such as hydrogen and/or argon. Electrode materials provided for the processing include nickel and titanium in some embodiments. Dielectric material properties include thickness and the dielectric constant. The process conditions for the post processing that may be varied include temperature, ramp profile and time for the post processing. It should be appreciated that the listing of variables, parameters, materials, etc. provided in FIGS. 3 and 4 is not meant to be limiting. That is, other processing parameters, materials, morphological properties, tests, etc., may be included in the matrices provided in order to efficiently identify an optimal graphene process through combinatorial processing techniques. In addition, various combinations of the processing parameters, materials, morphological properties, tests, etc., may be utilized for the testing.

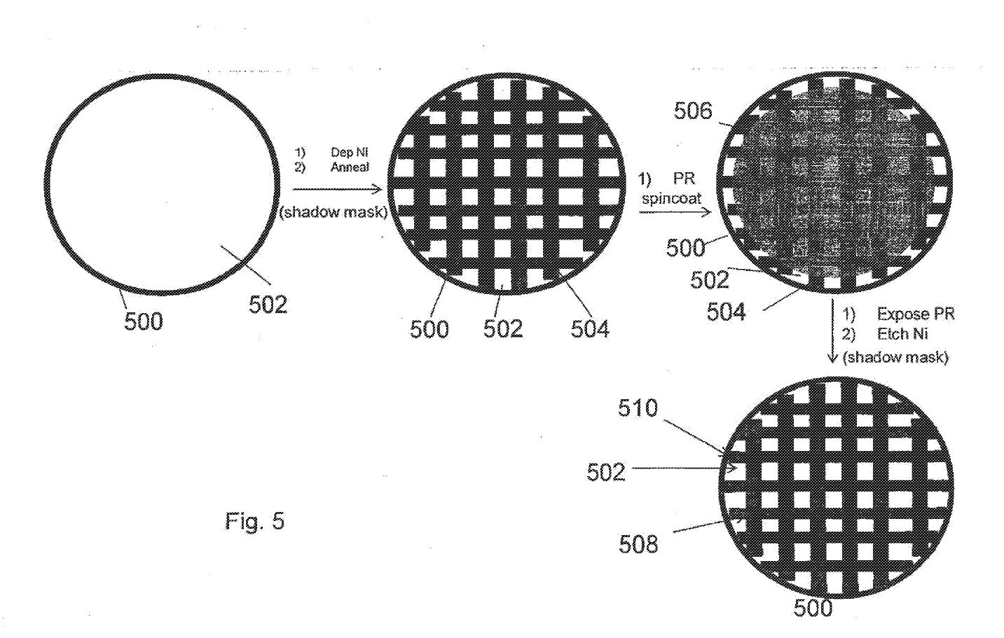

FIG. 5 is a simplified schematic diagram illustrating the process flow for the graphitization of an amorphous carbon layer disposed over any suitable substrate in accordance with some embodiments of the invention. In the process flow of FIG. 5, substrate 500 is shown initially with a layer of amorphous carbon 502 disposed thereon. It should be appreciated that the amorphous carbon may be deposited through a chemical vapor deposition process in accordance with some embodiments. In some embodiments the amorphous carbon is deposited through a vapor deposition process with the substrate held at a temperature of between about room temperature and about 500° C., which results in a ratio of sp³ to sp² hybridized bonds of about 10-50%, which is a non-conducting amorphous carbon layer. In addition, while FIG. 5 is explained in relation to substrate 500 having a layer of material disposed over the surface of the substrate, with the exception of the edge exclusion region around the periphery of substrate 500, this is not meant to be limiting. For example, the embodiments may be integrated into a combinatorial process where rather than an entire substrate having the amorphous carbon layer 502, a plurality of site isolated regions on the substrate may include the amorphous carbon layer 502. In this manner, the techniques and apparatuses described with reference to FIGS. 1-4 may be utilized for the combinatorial process flow to evaluate and identify an optimum process for forming graphene on the substrate.

Through a deposition process on substrate 500, a patterned array of metal lines 504 are deposited over the surface of substrate 500. In some embodiments, a vapor deposition process is performed to deposit the array of metal lines 504 on substrate 500 having the amorphous carbon layer 502. Following the deposition of the array of metal lines 504 an annealing process is performed. The annealing process occurs between about 120° C. and about 500° C. in some embodiments. The array of metal lines 504 may be composed of any transition metal. Example metals include nickel, cobalt, and iron in some embodiments. It should be appreciated that while a pattern of intersecting lines is illustrated, this is not meant to be limiting as any alternative pattern or entire region can be deposited. In addition, the metal layer can be deposited first as an underlayer and the carbon layer deposited over the underlayer in some embodiments. It should be appreciated that where the metal layer is deposited first different process parameters and process sequences may be employed for the formation of the graphene. Upon completion of the deposition and annealing process, a photoresist is disposed over region 506 on the surface of the patterned array on substrate 500. The photoresist over region 506 is exposed or developed and the array of metal lines 504 within a region 506 is etched in order to expose the graphene lines 508. In some embodiments, the etching is performed through a plasma enhanced process utilizing a shadow mask, however, alternative etching techniques may be employed. As a result of the exposure of the graphene 508, a plurality of graphitic lines in an amorphous carbon matrix is provided. In addition, metal contact pads 510 are provided around the periphery of substrate 500 and can function as electrodes in order to ascertain the electrical characteristics of the graphene lines 508.

It should be appreciated that the deposition of the transition metal and the subsequent annealing process converts the non-conducting amorphous carbon 502 disposed under the array of intersecting metal lines 504 to a conducting amorphous carbon, e.g., graphene. In some embodiments, the amorphous carbon is dissolved by the transition metal and subsequently re-crystallized during the annealing operation. That is, the amorphous carbon is exposed to the metal, a carbide is formed with the metal where the carbide is unstable and is transformed to graphene during the annealing operation. In some embodiments, the transforming of the non-conducting amorphous carbon layer 502 to a conducting graphene line 508 transforms the non-conducting sp³ hybridization bonds to conducting sp² hybridization bonds. In other embodiments, the non-conducting amorphous carbon may be composed of 50% sp³ hybridization bonds and 50% sp² hybridization bonds. In some embodiments, the conducting graphitized carbon contains 100% of sp² hybridization bonds, i.e., all of the sp³ hybridization bonds are converted to sp² hybridization bonds. The annealing process occurs at a temperature of less than 500° C. in some embodiments, which allows the process to be accommodated by currently available tools without modification as opposed to specialized tools for operating at temperatures above 900° C. In some embodiments the annealing process is between about 120° C. and about 900° C.

When compared to existing methods and apparatuses, the embodiments described can provide rapid combinatorial processing techniques which increase productivity in research and development of new materials, chemistries, and processing of semiconductor substrates and associated devices.

The corresponding structures, materials, acts, and equivalents of all means plus function elements in any claims below are intended to include any structure, material, or acts for performing the function in combination with other claim elements as specifically claimed.

Those skilled in the art will appreciate that many modifications to the exemplary embodiments are possible without departing from the spirit and scope of the present invention. In addition, it is possible to use some of the features of the present invention without the corresponding use of the other features. Accordingly, the foregoing description of the exemplary embodiments is provided for the purpose of illustrating the principles of the present invention, and not in limitation thereof, since the scope of the present invention is defined solely by the appended claims.

What is claimed:

1. A method for evaluating graphene synthesis processes, comprising:
providing a substrate having a plurality of site isolated regions defined thereon;
depositing a metal layer within each region of the plurality of site isolated regions, the metal layer deposited in a combinatorial manner among the plurality of site isolated regions;
synthesizing a graphene layer over each metal layer within each region of the plurality of site isolated regions; and
evaluating grain boundary profiles in the synthesized graphene layer over each metal layer within each region of the plurality of site isolated regions.

2. The method of claim 1, further comprising:
selecting a region of the plurality of site isolated regions based on a grain boundary profile;
depositing the metal layer within the selected region having the grain boundary profile onto a plurality of site isolated regions of a second substrate;
synthesizing a graphene layer over each metal layer within each region of the plurality of site isolated regions of the second substrate, wherein the synthesizing parameters are varied across the plurality of site isolated regions of the second substrate in a combinatorial manner; and
evaluating electrical properties of each graphene layer of the second substrate.

3. The method of claim 1, wherein the metal layer comprises nickel.

4. The method of claim 1, wherein the metal layer comprises a nickel alloy.

5. The method of claim 1, wherein the metal layer comprises aluminum.

6. The method of claim 1, wherein the depositing the metal layer comprises modifying a composition of the metal layer within each region.

7. The method of claim 1, wherein the synthesizing comprises varying a component ratio of a deposition source of the graphene layer.

8. The method of claim 6, wherein the deposition source is a mixture of methane and hydrogen.

9. The method of claim 2, wherein the synthesizing parameters include temperature, pressure, and power parameters.

10. A method for combinatorially processing graphene, comprising:
providing a substrate having a plurality of site isolated regions defined thereon;
depositing a metal layer within each region of the plurality of site isolated regions, wherein a composition of at least one metal layer varies from remaining metal layers in a combinatorial manner;
forming a graphene layer over each metal layer within each region of the plurality of site isolated regions; and
evaluating morphological properties in the synthesized graphene layer over each metal layer within each region of the plurality of site isolated regions.

11. The method of claim 10, wherein the morphological properties include thickness, crystallinity and grain size.

12. The method of claim 10, further comprising:
selecting a region with the graphene layer based on morphological properties;
depositing the metal layer within the selected region having the morphological properties onto a plurality of site isolated regions of a second substrate;
combinatorially synthesizing a graphene layer over each metal layer within each region of the plurality of site isolated regions of the second substrate; and
evaluating electrical properties of each graphene layer of the second substrate.

13. The method of claim 12, wherein the combinatorially synthesizing includes varying a processing parameter for the synthesizing the graphene layer between site isolated regions of the second substrate.

14. The method of claim 10, wherein the metal layer comprises nickel.

15. The method of claim 10, wherein the metal layer comprises a nickel alloy.

16. The method of claim 10, wherein the metal layer comprises aluminum.

17. The method of claim 10, wherein the forming comprises varying a component ratio of a deposition source of the graphene layer.

18. The method of claim 17, wherein the deposition source is a mixture of methane and hydrogen.

19. The method of claim 10, wherein the depositing the metal layer comprises modifying a composition of the metal layer within each region and wherein the depositing is a vapor deposition process.
